(19) United States
(12) Patent Application Publication
(10) Pub. No.: US 2005/0167810 A1
(43) Pub. Date: Aug. 4, 2005

(54) Stacked semiconductor device

(75) Inventors: Jin-Chung Bai, Taipei County (TW); Kuang-Pao Cheng, Hsinchu City (TW); Chi-Pang Huang, Taoyuan County (TW)

Correspondence Address: BACON & THOMAS, PLLC, 625 SLATERS LANE, FOURTH FLOOR, ALEXANDRIA, VA, 22314, US

(73) Assignee: STACK DEVICES CORP., Miaoli County (TW)

(21) Appl. No.: 10/806,166

(22) Filed: Mar. 23, 2004

(30) Foreign Application Priority Data
Jan. 29, 2004 (TW) 93102059

(51) Int. Cl. H01L 23/02

(52) U.S. Cl. 257/686

(57) ABSTRACT

A stacked semiconductor device has a substrate having a conductor pattern and a die bonding portion. A first die is bonded on the die bonding portion of the substrate and is electrically connected to the conductor pattern via wires. A first adhesive layer provided on the substrate to cover the first die and the wires. The first adhesive layer has a greater top on which a second die is bonded. The second die is greater than the first die and is electrically connected to the pads of the conductor pattern via wires. A second adhesive layer provided on the substrate to cover the second die and the wires.

### BACKGROUND OF THE INVENTION

1. Field of the Invention

The present invention relates generally to a semiconductor device, and more particularly to a stacked semiconductor device, which allows the die with greater size stacked on the die with smaller size.

2. Description of the Related Art

FIG. 8 shows a conventional stacked semiconductor device 60, which has a substrate 62 on which a plurality of dies 64, 66 and 68 are stacked. The substrate 62 has a conductor pattern 70 thereon and the dies 64, 66 and 68 are electrically connected to the conductor pattern 70 respectively via gold wires 72, 74 and 76. On the dies 64 and 66 and on the substrate 62 are respectively provided with an adhesive layer 78 to bond the dies 64, 66 and 68 on the substrate 62.

The conventional stack structure has to make the smaller dies stacked on the greater dies in sequence. There will be an unstable stack condition while a greater die stacked on a smaller die. In addition, the gold wires are exposed that might get damage in fabrication.

### SUMMARY OF THE INVENTION

The primary objective of the present invention is to provide a stacked semiconductor device, which has a stable stack condition.

The secondary objective of the present invention is to provide a stacked semiconductor device, which allows the greater die stacked on the smaller die.

According to the objectives of the present invention, a stacked semiconductor device comprises a substrate having a conductor pattern and a die bonding portion, wherein the conductor pattern has pads. A first die is bonded on the die bonding portion of the substrate. The first die is electrically connected to the pads of the conductor pattern. A first adhesive layer provided on the substrate to cover the first die. A second die is bonded on the top of the first adhesive layer and is electrically connected to the pads of the conductor pattern.

### BRIEF DESCRIPTION OF THE DRAWINGS

FIG. 1 to FIG. 7 are sectional view of a preferred embodiment of the present invention, showing how the dies stacked.

### DETAILED DESCRIPTION OF THE INVENTION

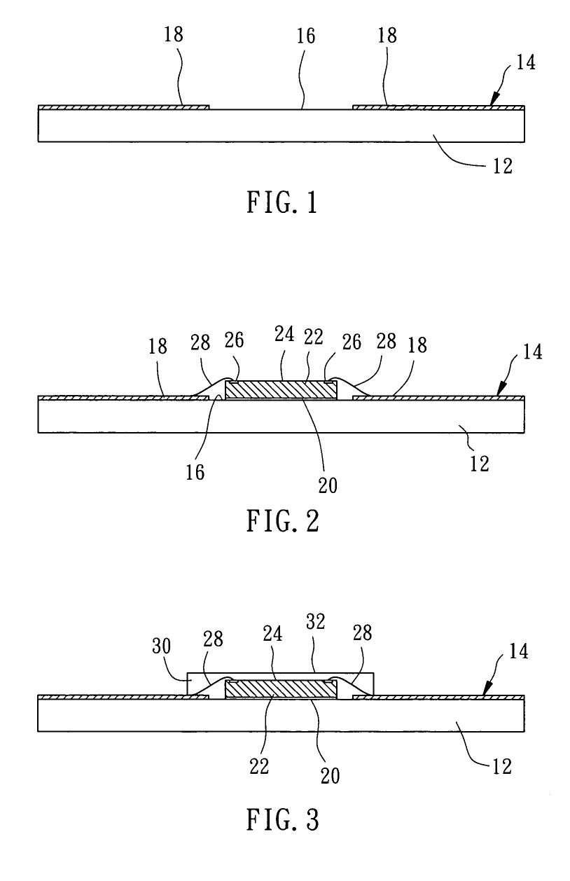

FIG. 1 to FIG. 7 are shown as a flow chart that help the one who may concern our invention to understand the structure of a stacked semiconductor device 10 of the preferred embodiment of the present invention.

As shown in FIG. 1, the stacked semiconductor device 10 has a substrate 12 on which a conductor pattern 14 and a die bonding portion 16 are provided. The conductor pattern 14 has a plurality of pads 18 around the die bonding portion 16. An adhesive layer 20 is provided on the die bonding portion 16 of the substrate 12 and a first die 22 is struck on the adhesive layer 20. In other words, the first die 22 is bonded on the die bonding portion 16 of the substrate 12 via the adhesive layer 20. The first die 22 is electrically connected to the pads 18 of the conductor pattern 14 by wire bonding as shown in FIG. 2.

The first die 22 has a top 24 on which a plurality of pads 26 are provided. A plurality of gold wires 28 have ends thereof connected to the pads 26 of the first die 22 and have the other ends thereof connected to the pads 18 of the conductor pattern 14.

As shown in FIG. 3, a first adhesive layer 30 is provided on the substrate 12 to cover the first die 22 and the gold wires 28. The first adhesive layer 30 has a top 32 that is greater than the top 24 of the first die 22. The first adhesive layer 30 can be made by printing or other suitable ways and the first adhesive layer 30 can be made of epoxy resin or other insulating materials.

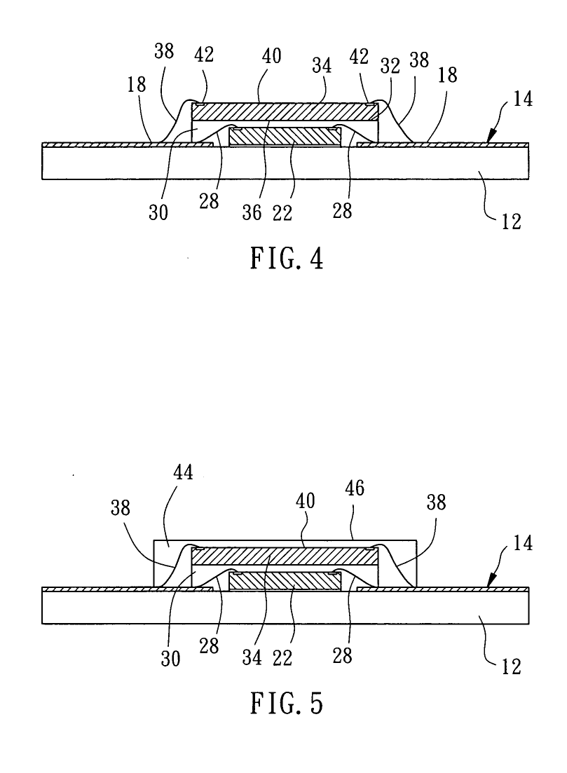

As shown in FIG. 4, a second die 34 is bonded on the top 32 of the first adhesive layer 30. The second die 34 has a bottom 36 and a top 40. The second die 34 is greater than the first die 22 and the bottom 36 thereof is substantially equal to the top 32 of the first adhesive layer 30. The second die 34 is provided with a plurality of gold wires 38 to electrically connect pads 38 on the top 40 of the second die 34 to the pads 18 of the conductor pattern 14.

As shown in FIG. 5, an second adhesive layer 44 is printed on the substrate 12 to cover the second die 34 and the gold wires 38. The second adhesive layer 44 has a top 46, which is greater than the top 40 of the second die 34.

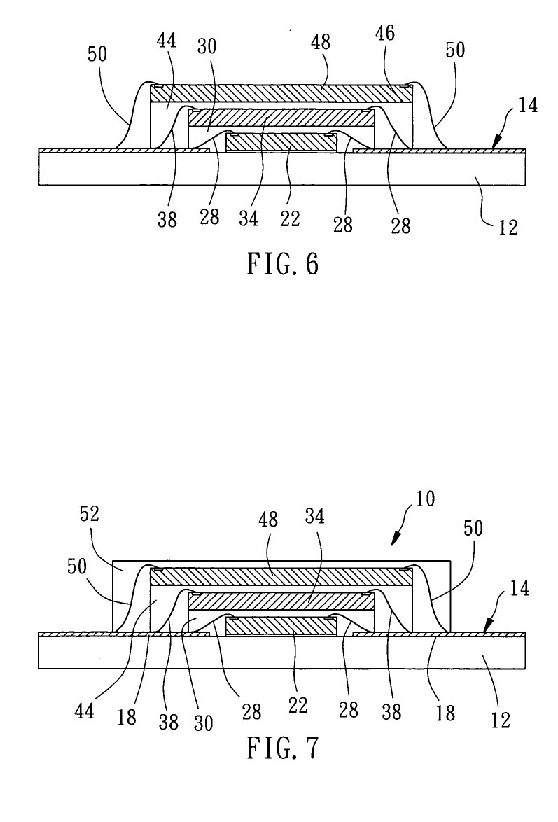

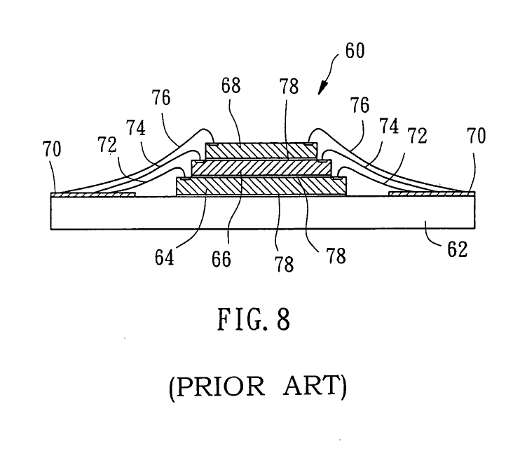

As shown in FIG. 6, a third die 48 is bonded on the top 46 of the second adhesive layer 44 and is electrically connected to the conductor pattern 14 via gold wires 50. A third adhesive layer 52 is printed on the substrate 12 to cover the third die 48 and the gold wires 50 as shown in FIG. 7.

It is easy to understand that a fourth die, a fifth die . . . (not shown) can be bonded on the third adhesive layer 52 in sequence as described above.

The present invention provides the stacked semiconductor device 10 has the dies 22, 34 and 48 in stack in the condition of the greater dies stacked on the smaller dies. The present invention has a flexible stack condition without the restrict of the conventional device that the smaller dies have to be stacked on the greater dies.

The dies 22, 34 and 48 have the whole bottom bonded on the adhesive layers 20, 30 and 44 respectively that make the stack of dies having a stronger structure. In addition, the gold wires 28, 38 and 50 are all covered by the adhesive layers 30, 44 and 52. In other words, the adhesive layers protect the gold wires from damage.

Please compare FIG. 7 and FIG. 8, the pads 18 of the conductor pattern 14 at where the gold wires 28, 38 and 50 are bonded is proximal to a center of the stack of dies, which means the semiconductor device 10 of the present invention has a smaller size than the conventional device.

It has to be mentioned that the first die can be electrically connected to the conductor pattern by flip chip rather than by wire bonding and the first adhesive layer still has a greater size than the first die and the top of the first adhesive layer is substantially equal to the second die.

1. A stacked semiconductor device, comprising:
a substrate having a conductor pattern and a die bonding portion, wherein the conductor pattern has pads;
a first die bonded on the die bonding portion of the substrate and having pads thereon, wherein the pads of the first die are electrically connected to the pads of the conductor pattern by wires;
a first adhesive layer provided on the substrate to cover the first die and the wires, wherein the first adhesive layer has a top and a portion of said adhesive layer contiguous with the substrate, and
a second die bonded on the top of the first adhesive layer and having pads thereon, wherein the pads of the second die are electrically connected to the pads of the conductor pattern by wires.

2. The stacked semiconductor device as defined in claim 1, further comprising a second adhesive layer provided on the substrate to cover the second die and the wires.

3. The stacked semiconductor device as defined in claim 1, wherein a size of the top of the first adhesive layer is greater than a size of a top of the first die.

4. The stacked semiconductor device as defined in claim 1, wherein a size of the top of the first adhesive layer is substantially equal to a size of a bottom of the second die.

5. The stacked semiconductor device as defined in claim 1, wherein a size of the first die is smaller than a size of the second die.

6. A stacked semiconductor device, comprising:
a substrate having a conductor pattern and a die bonding portion, wherein the conductor pattern has pads;
a first die bonded on the die bonding portion of the substrate and having pads thereon, wherein the first die is electrically connected to the pads of the conductor pattern;
a first adhesive layer provided on the substrate to cover the first die, wherein the first adhesive layer has a top and the size of the top thereof is greater than the size of the first die and a portion of said adhesive layer contiguous with the substrate, and
a second die bonded on the top of the first adhesive layer and electrically connected to the pads of the conductor pattern, wherein the size of the second die is greater than the size of the first die.

7. The stacked semiconductor device as defined in claim 6, further comprising a second adhesive layer provided on the substrate to cover the second die.

8. The stacked semiconductor device as defined in claim 7, wherein the second die is electrically connected to the pads of the conductor pattern by wires and the second adhesive layer covers both of the second die and the wires.

9. The stacked semiconductor device as defined in claim 6, wherein the first die is electrically connected to the pads of the conductor pattern by wires and the first adhesive layer covers both of the first die and the wires.

10. The stacked semiconductor device as defined in claim 6, wherein a size of the top of the first adhesive layer is substantial equal to a size of a bottom of the second die.
